(19) United States
(12) Patent Application Publication
(10) Pub. No.: US 2026/0190350 A1
(43) Pub. Date: Jul. 2, 2026

(54) Programmable Heterojunction Memory Device With Current Blocking

(71) Applicant: Chengdu PBM Technology Ltd, Chengdu, Sichuan (CN)

(72) Inventors: Ke Wang, Chengdu, Sichuan (CN); Jack Zezhong Peng, Chengdu, Sichuan (CN)

(73) Assignee: Chengdu PBM Technology Ltd, Chengdu, Sichuan (CN)

(21) Appl. No.: 18/728,585

(22) PCT Filed: Nov. 29, 2023
(86) PCT No.: PCT/CN2023/134876

§ 371 Date: Jul. 12, 2024

(30) Foreign Application Priority Data
Aug. 10, 2023 (CN) 202311008148.5

(51) Int. Cl. H10B 63/10; H10B 20/25; H10B 63/00; H10N 70/00; H10N 70/20

(52) U.S. Cl. CPC H10B 63/10; H10B 20/25; H10N 70/231; H10N 70/841; H10B 63/80

(57) ABSTRACT

Disclosed is a programmable heterojunction memory device with current blocking, relating to the field of memory devices. The memory device includes: a first electrode, a current-blocking heterojunction insulating medium layer, and a second electrode that are sequentially connected; the current-blocking heterojunction insulating medium layer includes a current-blocking layer and a programmable medium layer; the current-blocking layer and the programmable medium layer use different insulating media; the first electrode and the second electrode are made of designated matching materials; a bandgap width of the current-blocking layer is smaller than a bandgap width of the programmable medium layer. The memory device can achieve low-cost, high-density storage.

### CROSS REFERENCE TO RELATED APPLICATION

The present application is a national stage application of International Patent Application No. PCT/CN2023/134876, filed on Nov. 29, 2023, which claims the benefit and priority of Chinese Patent Application No. 202311008148.5, filed with the China National Intellectual Property Administration on Aug. 10, 2023 and entitled “PROGRAMMABLE HETEROJUNCTION MEMORY DEVICE WITH CURRENT BLOCKING”, the disclosure of which is incorporated by reference herein in its entirety as part of the present application.

### TECHNICAL FIELD

The present disclosure relates to the field of memory devices, and in particular, to a programmable heterojunction memory device with current blocking.

### BACKGROUND

Memory devices in the prior art include a 3D multi-layer stacked memory array with characteristics of low cost and high storage density. For example, in patents CN101615656A and CN109545787A, horizontal word lines (WL) and vertical bit lines (BL) made of materials with opposite conductivity types, with a programmable insulating medium placed at their intersections, form a memory cell.

The characteristic of such 3D multi-layer stacked memory arrays is the opposite conductivity types of WL and BL, such as p-type/n-type heavily-doped polysilicon. When the programmable medium layer transforms into a low-resistance state due to programming, e.g., when the insulating medium is electrically broken down to become a conductive medium in an anti-fuse one-time programmable (OTP) memory, the BL and WL automatically form a one-way conducting diode. The advantage of this setup is that it still effectively controls 3D multi-layer stacked memory array with extremely high storage density, without the need for additional space to set up diode devices, thus lowering production costs.

However, in reality, any diode always has a certain amount of reverse current. If the reverse current is large, the stability of programming voltage cannot be maintained, leading to an operational failure. Such operational failure can occur in normal circumstances especially when the memory array is large in scale and high in integration level, for example, when the memory array has 128 layers and a capacity of 1 Mbit for each single layer. The larger the memory array, the stricter are the requirements for the control of the reverse current. Therefore, to ensure the operational stability of the memory, a semiconductor material layer is added as a buffer layer between the insulating storage medium and the WL or BL for memory cells of such a 3D multi-layer stacked memory array. For example, in patent CN109545787A, a medium layer placed in the middle of the unit device can be composed of two parts: a storage insulating medium and a lightly-doped semiconductor. The lightly-doped semiconductor has the same conductivity as the WL or BL in direct contact and a lower doping concentration, and is generally lightly-doped polysilicon. This can effectively control the magnitude of the reverse current by optimizing the thickness of the buffer layer, without affecting the unidirectional conductivity of the diode.

The characteristic of this method is that the thicker the buffer layer, the smaller the reverse current. However, the thickness of the buffer layer often occupies chip area, especially when the size of the memory cell is further reduced to below deep sub-micron to increase storage density, the buffer layer still occupies a considerable proportion of the area of the memory cell, limiting a further increase in memory density. Additionally, because the buffer layer generally needs to be deposited on sidewalls of memory holes with a high aspect ratio, if crystallined semiconductors, such as lightly-doped polysilicon, are used as the buffer layer, the implementation cost of the process is high, because thin films prepared by atomic layer deposition (ALD), which controls thickness uniformity well, are mostly in disordered phases, and doping concentration is not easily controlled. Therefore, the prior art often needs to consider compromises in terms of device performance, chip area occupancy (storage density), and process costs.

### SUMMARY

An objective of the present disclosure is to provide a programmable heterojunction memory device with current blocking, which can achieve low-cost, high-density storage.

To achieve the above objective, the present disclosure provides the following technical solutions.

A programmable heterojunction memory device with current blocking is provided, where the memory device includes: a first electrode, a current-blocking heterojunction insulating medium layer, and a second electrode that are sequentially connected.

The current-blocking heterojunction insulating medium layer includes: a current-blocking layer and a programmable medium layer.

The current-blocking layer and the programmable medium layer use different insulating media; the first electrode and the second electrode are made of preset matched materials; a bandgap width of the current-blocking layer is smaller than a bandgap width of the programmable medium layer; and no additional contact potential barrier is formed between the current-blocking layer and the first electrode or the second electrode in direct contact.

Optionally, the insulating medium used for the programmable medium layer is an anti-fuse insulating medium, a resistive non-volatile storage medium, or a phase-change non-volatile storage medium.

Optionally, the anti-fuse insulating medium is made of silicon oxide or aluminum oxide.

Optionally, the insulating medium used for the current-blocking layer includes a charge-transfer insulator or an electrical insulator.

Optionally, the charge-transfer insulator includes a TiO₂, ZnO, or HfO₂ thin film.

Optionally, the electrical insulator includes intrinsic SiC.

Optionally, the current-blocking layer is in a crystalline, polycrystalline, or amorphous form; and the current-blocking layer is an amorphous HfO₂ thin film, amorphous SiC thin film, or amorphous silicon thin film.

Optionally, the designated matching materials include four sets of matching materials;
the first electrode is a P-type semiconductor or conductor, and the second electrode is an N-type semiconductor;
or, the first electrode is a P-type Schottky metal, and the second electrode is an N+ semiconductor or conductor;
or, the first electrode is an N+ semiconductor or conductor, and the second electrode is a P+ semiconductor;
or, the first electrode is an N-type Schottky metal, and the second electrode is a P+ semiconductor or conductor.

Optionally, the P-type Schottky metal is Au or Pt.

Optionally, the N-type Schottky metal is Al.

According to specific embodiments provided in the present disclosure, the present disclosure has the following technical effects:

The present disclosure provides a programmable heterojunction memory device with current blocking. Due to the addition of the insulating current-blocking layer, insulating properties of the insulating current-blocking layer significantly reduce the tunneling effect of the reverse current. This can ensure extremely low reverse current even with a small thickness of the current-blocking layer and a small chip area occupation, without the need for crystal semiconductors for buffering, making the process cost lower. The insulating media used for the current-blocking layer and the programmable medium layer are different, the bandgap width of the current-blocking layer is smaller than that of the programmable medium layer, and no additional contact potential barrier is formed between the current-blocking layer and the first or second electrode in contact. Therefore, the addition of the current-blocking layer does not affect the current-voltage characteristics of the device in forward operation. Therefore, the present disclosure can achieve low-cost, high-density storage.

### BRIEF DESCRIPTION OF THE DRAWINGS

To describe the technical solutions in embodiments of the present disclosure or in the prior art more clearly, the accompanying drawings required in the embodiments are briefly described below.

Apparently, the accompanying drawings in the following description show merely some embodiments of the present disclosure, and other drawings can be derived from these accompanying drawings by those of ordinary skill in the art without creative efforts.

FIG. 1 is a structural diagram of a programmable heterojunction memory device with current blocking according to an embodiment of the present disclosure;

FIG. 2 is a schematic diagram of a programmable heterojunction memory device with current blocking according to an embodiment of the present disclosure;

FIG. 3 is a structural diagram of a first type of semiconductor device in the prior art according to an embodiment of the present disclosure;

FIG. 4 is a structural diagram of a second type of semiconductor device in the prior art according to an embodiment of the present disclosure;

FIG. 5 is a schematic diagram of an application circuit of a programmable heterojunction memory device with current blocking according to an embodiment of the present disclosure;

FIG. 6 is a structural diagram of a device bandgap according to an embodiment of the present disclosure;

FIG. 7 is a diagram of an electric field distribution when an external forward voltage is 6V according to an embodiment of the present disclosure;

FIG. 8 is a comparison diagram of values of reverse currents with and without a current-blocking layer when a programmable medium layer is in a low-resistance state according to an embodiment of the present disclosure; and

FIG. 9 is a comparison diagram of values of forward currents with and without a current-blocking layer when a programmable medium layer is in a low-resistance state according to an embodiment of the present disclosure.

### DESCRIPTION OF REFERENCE NUMERALS

1: first electrode; 2: current-blocking heterojunction insulating medium layer; 3: second electrode; 4: current-blocking layer; 5: programmable medium layer.

### DETAILED DESCRIPTION OF THE EMBODIMENTS

The technical solutions of the embodiments of the present disclosure are clearly and completely described below with reference to the drawings in the embodiments of the present disclosure. Apparently, the described embodiments are merely a part rather than all of the embodiments of the present disclosure. All other embodiments obtained by those skilled in the art based on the embodiments of the present disclosure without creative efforts shall fall within the protection scope of the present disclosure.

An objective of the present disclosure is to provide a programmable heterojunction memory device with current blocking, which can achieve low-cost, high-density storage.

In order to make the above objective, features and advantages of the present disclosure clearer and more comprehensible, the present disclosure will be further described in detail below in combination with accompanying drawings and particular implementation modes.

### Embodiment 1

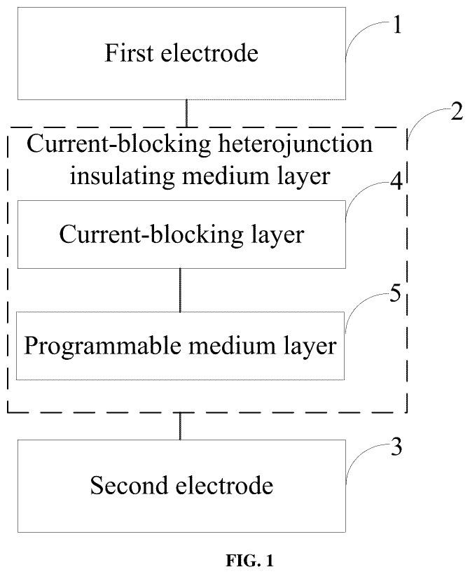

As shown in FIG. 1, this embodiment of the present disclosure provides a programmable heterojunction memory device with current blocking. The memory device includes: a first electrode 1, a current-blocking heterojunction insulating medium layer 2, and a second electrode 3 that are sequentially connected.

The current-blocking heterojunction insulating medium layer 2 includes: a current-blocking layer 4 and a programmable medium layer 5.

The current-blocking layer 4 and the programmable medium layer 5 use different insulating media; the first electrode 1 and the second electrode 3 are made of designated matching materials; a bandgap width of the current-blocking layer 4 is smaller than a bandgap width of the programmable medium layer 5; and no additional contact potential resistance is formed between the current-blocking layer and the first electrode 1 or the second electrode 3 in direct contact, that is, no additional contact potential barrier is formed.

Specifically, the insulating material used for the programmable medium layer 5 is a programmable non-volatile storage medium, such as an anti-fuse insulating medium. The anti-fuse insulating medium is made of silicon oxide or aluminum oxide.

Alternatively, the insulating medium used for the programmable medium layer 5 may be a resistive non-volatile storage medium or a phase-change non-volatile storage medium.

The insulating medium used for the current-blocking layer 4 is a charge-transfer insulator or an electrical insulator. The charge-transfer insulator is a TiO₂, ZnO, or HfO₂ thin film. The electrical insulator compound includes intrinsic SiC.

The current-blocking layer 4 is in a crystalline, polycrystalline, or amorphous form.

Specifically, the bandgap width of the current-blocking layer 4 is lower than that of the programmable medium layer 5, and the electron affinity of the current-blocking layer 4 matches the work function of the material of the adjacent electrode (first electrode 1 or second electrode 3), so that no additional contact potential barrier is formed between them. Specifically, the material required for the current-blocking layer 4 can be a charge-transfer insulator, such as a TiO₂, ZnO, or HfO₂ thin film, or an electrical insulating compound, such as intrinsic SiC, and its thin film form can be crystalline, polycrystalline, or amorphous. For example, the charge-transfer insulator can be an amorphous HfO₂ thin film, amorphous SiC thin film, or amorphous silicon thin film, etc., with a typical thickness of 10 nm to 30 nm.

A preparation process of the current-blocking layer 4 includes an atomic layer deposition (ALD) technology, a chemical vapor deposition (CVD) technology, etc. The current-blocking layer 4 can be crystalline, polycrystalline, or amorphous, such as an amorphous TiO₂ thin film, amorphous SiC thin film, and amorphous carbon or silicon thin film, etc.

Specifically, the programmable medium layer 5 can be an anti-fuse insulating medium programmable with dielectric breakdown.

The programmable medium layer 5 can also use a resistive non-volatile storage medium, such as TaO₂, or a phase-change non-volatile storage medium, such as Ge2Sb2Te5 and other sulfur-based compounds.

For example, if the programmable medium is silicon oxide with a bandgap width of 9 eV, the current-blocking layer 4 can use an insulating medium with a bandgap width of 3-7 eV, such as HfO₂ or ZrO₂ with a bandgap width of about 5.5 eV, or TaO₂ with a bandgap width of about 4 eV. The anti-fuse insulating medium that can be broken down is, for example, such as SiO₂ or Al₂O₃, with a typical thickness of 0.5 to 5 nm.

A preparation process of the programmable medium layer 5 includes an atomic layer deposition (ALD) technology, a chemical vapor deposition (CVD) technology, etc.

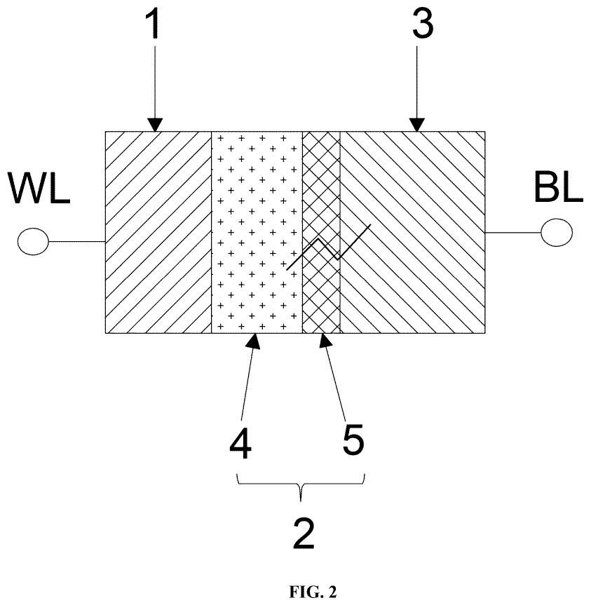

There are no specific shape requirements for the current-blocking heterojunction insulating medium layer 2, the first electrode 1, and the second electrode 3. As long as the stacking sequence described above is followed, the programmable heterojunction memory device with current blocking provided by the present disclosure, as shown in FIG. 2, can be obtained.

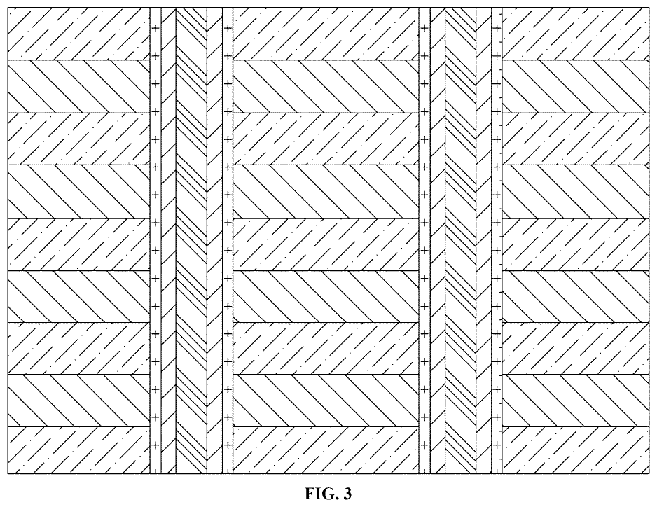

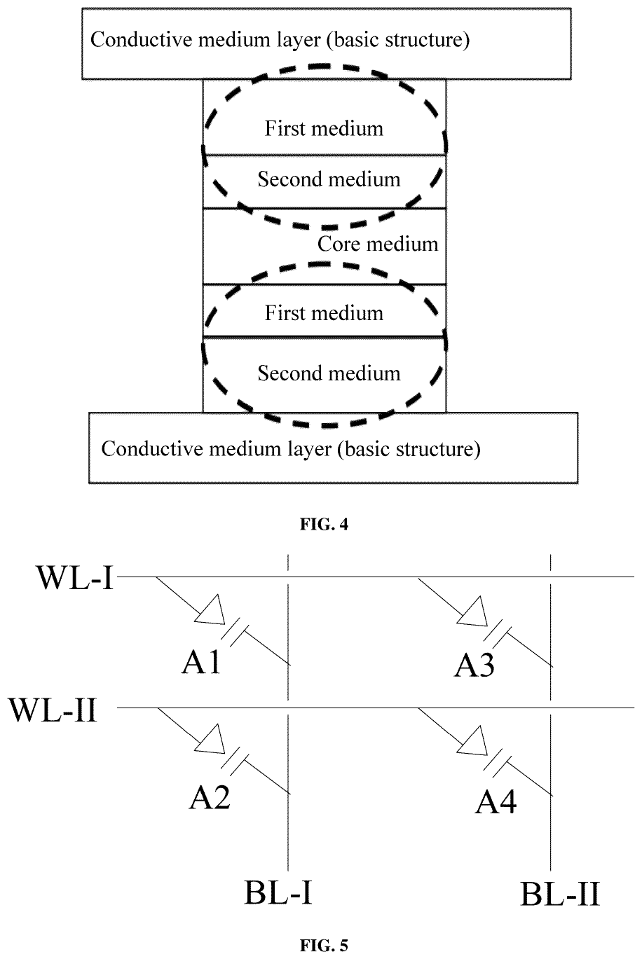

Due to its insulation, the current-blocking layer 4 significantly reduces the tunneling effect of the reverse current. Compared with the semiconductor materials in the prior art shown in FIG. 3 and FIG. 4, it can still ensure an extremely low reverse current even with a small layer thickness and a small chip area occupation. Moreover, the present disclosure can use amorphous thin films, which further reduces the process cost. Therefore, low-cost, high-density storage can be achieved.

In one embodiment, the designated matching materials include four sets of matching materials. The first electrode 1 is a P-type semiconductor or conductor, and the second electrode 3 is an N-type semiconductor; or, the first electrode 1 is a P-type Schottky metal, and the second electrode 3 is an N+ semiconductor or conductor; or, the first electrode 1 is an N+ semiconductor or conductor, and the second electrode 3 is a P+ semiconductor; or, the first electrode 1 is an N-type Schottky metal, and the second electrode 3 is a P+ semiconductor or conductor.

Specifically, the P-type Schottky metal is Au or Pt. The N-type Schottky metal is Al.

FIG. 5 is an application schematic diagram of a programmable heterojunction memory device with current blocking according to the present disclosure. In FIG. 5, A1, A2, A3, and A4 are all programmable memory devices. The symbol of the programmable memory device can be equivalent to a capacitor symbol and a diode symbol, indicating that the insulating medium and the electrode materials at both ends of this memory cell form a capacitor, and due to the different conductivity types of the electrode materials at both ends, when the insulating medium layer is switches from a high-resistance state to a low-resistance state due to programming, the entire memory cell exhibits diode characteristics. It should be noted that when the insulating medium layer is in a high-resistance state, it does not exhibit diode characteristics.

In general, in a three-dimensional memory device, the first electrode 1 serves as a bit line BL in a pillar shape, which is vertically connected downward to a bit line decoder in an underlying circuit, and the second electrode 3 serves as a word line WL, which is a long horizontal conductor connected to word line decoders at both ends. Alternatively, the second electrode 3 serves as a bit line BL in a pillar shape, which is vertically connected downward to a bit line decoder in the underlying circuit, and the first electrode 1 serves as a word line WL, which is a long horizontal conductor connected to word line decoders at both ends. The insulating medium layer is located at projection of an intersection of the first electrode 1 and the second electrode 2, and connects the two. It is generally required that the thickness of the insulating medium layer be uniform to maintain function consistency.

The function of such devices mainly stays in three different states, and the working conditions to be ensured are as follows:
(1) Writing: The diode needs to be in a forward bias state, and the programming voltage applied to the programmable medium layer 5 reaches the dielectric strength required for anti-fuse breakdown. If breakdown occurs, the stored data changes from 0 to 1.
(2) Reading: The diode needs to be in a forward bias state, and the reading voltage exceeds the diode threshold voltage. If the device is turned on, the readout is 1, if the device is turned off, the readout is 0.
(3) Idle: One of the two electrodes is in a floating state.

When the selected and unselected word lines and bit lines of the 3D memory device are interleaved and work together, there is a situation where idle memory cells are subjected to reverse bias. By reducing the reverse current when the programmable medium layer 5 of the memory cell is in the low-resistance state, it is possible to ensure that the entire 3D memory array operates orderly. For example, in FIG. 5, when only the memory cell A1 is programmed and other cells are idle, WL-I and BL-I are connected to the high and low levels of the programming voltage, respectively. The other electrodes, WL-II and BL-II, are floating. If at this time the memory devices A2 and A4 have been programmed to the low-resistance state, and the diode of A4 has ideal reverse characteristics, the states of the memory cells remain unchanged; if the reverse current of A4 is large, A2 and A4 will form a current path, causing the potential of the floating WL-II to be pulled up, which may change the state of A3 from idle to writing. Alternatively, if at this time the memory devices A2, A3, and A4 are all in the low-resistance state, and the reverse current of A4 is large, A2, A4, and A3 will form a current path, which may cause the potential of the floating BL-I to be pulled up, thereby causing the programming voltage at both ends of A1 to decrease, leading to a programming failure.

In the present disclosure, in order to ensure the stable operation of the programmable memory device, the insulating storage medium layer is formed by stacking the programmable medium layer 5 and the current-blocking layer 4. The current-blocking layer 4 is an insulating thin film layer with a bandgap width narrower than the programmable medium, and the electron affinity of the current-blocking layer 4 matches the work function of the electrode material in contact, so that no additional potential barrier of the majority carrier in transport is formed between the two. Since the bandgap width of the current-blocking layer 4 material is narrower than that of the programmable medium, during programming, the electric field applied to the current-blocking layer 4 and the programmable medium layer 5 is mostly concentrated on the programmable medium. Therefore, the addition of the current-blocking layer 4 has minimal impact on the programming process of the working state (1).

At the same time, the current-blocking layer 4 formed by the insulating material also reduces the forward current to a certain extent.

From the above working conditions, it can be seen that with the forward bias, there are only two working states, (1) and (2), which are high-voltage programming driven by the electric field and low-voltage data reading. In the first case, which is the electric field-driven process, there is no high requirement for the magnitude of the forward conducting current, and it is only required that the electric field be mostly concentrated on the programmable medium layer 5; in the second case, after the programmable medium layer 5 is broken down in state (1), data reading can be achieved by appropriately increasing the reading voltage and/or reducing the threshold current. Therefore, the addition of the current-blocking layer 4 does not affect normal reading and writing functions.

It should be noted that, the key of this method to effectively reduce the reverse current under a reverse bias is, not simply due to connecting a backward-biased pn junction and the high resistance of the insulating current-blocking layer 4 in series, which, otherwise, would have the same impact on both forward and reverse currents; but due to effectively suppressing the band-to-band tunneling effect of the diode by sandwiching the current-blocking layer 4 with a bandgap wider than a semiconductor, between the two electrodes, that is, between the p-type and n-type conductors (or semiconductors), thus significantly reducing the reverse current. Therefore, by ensuring that the current-blocking layer 4 is an insulating thin film layer with a bandgap width narrower than the programmable medium, even with a small film thickness, it can greatly reduce the reverse current of a device with a broken-down programmable medium layer 5.

Furthermore, this method does not strictly require the conductivity and crystallinity of the current-blocking layer 4. If amorphous thin films are used, the preparation cost is effectively reduced. Especially in 3D memory devices, it is usually necessary to deposit films in deep trenches with a high aspect ratio. The preparation cost of polycrystalline films is very high, while amorphous films have relatively low preparation cost. Therefore, this method can ensure a low reverse current without affecting the reading/writing of the memory and the chip area occupancy, and with relatively easier process, it can achieve low-cost, high-density storage.

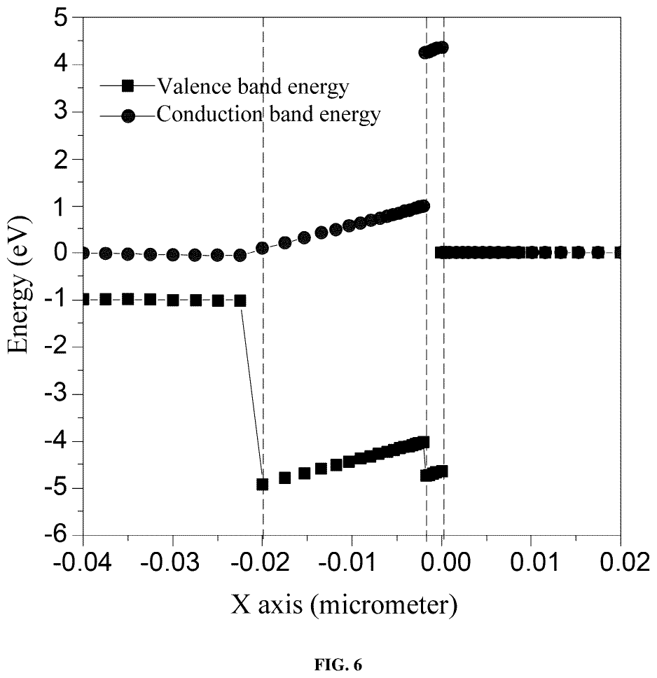

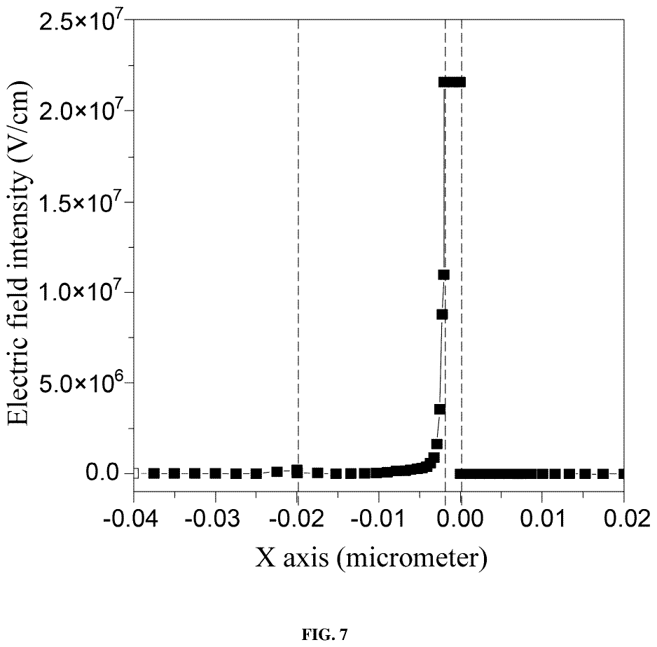

A specific implementation embodiment is given by using one of the combinations of preset matched materials, as shown in FIG. 6 from left to right, the first electrode 1, the current-blocking layer 4, the programmable medium layer 5, and the second electrode 3. The first electrode 1 is an n-type semiconductor, the second electrode 3 is a p-type conductor, and the current-blocking layer 4 adopts an insulating material with a bandgap width lower than that of the programmable medium, with a thickness of 18 nm; the programmable medium layer 5 uses a common anti-fuse material, silicon dioxide SiO₂, with a thickness of 2 nm.

FIG. 6 shows the band structure of the device with various components combined. FIG. 6 demonstrates that the bandgap width of the current-blocking layer 4 is lower than that of the programmable medium, and the electron affinity of the current-blocking layer 4 is equal to the work function of the first electrode in contact, i.e., the first electrode 1, which are both at 4.17 eV, That is, no additional potential barrier of the carrier in transport is formed between the current-blocking layer 4 and the first electrode 1, and the conductivity properties of the first electrode 1 and the second electrode 3 can be demonstrated.

FIG. 7 shows the electric field distribution of the components when an external positive voltage of 6V is applied. Simulation results show that the introduction of the current-blocking layer 4 does not affect the high electric field required for the writing state when the programmable medium layer 5 is in a high-resistance state.

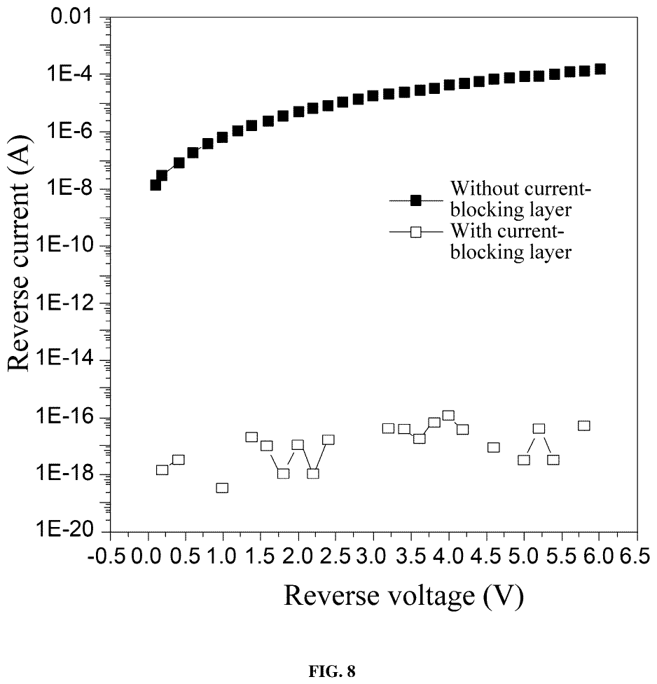

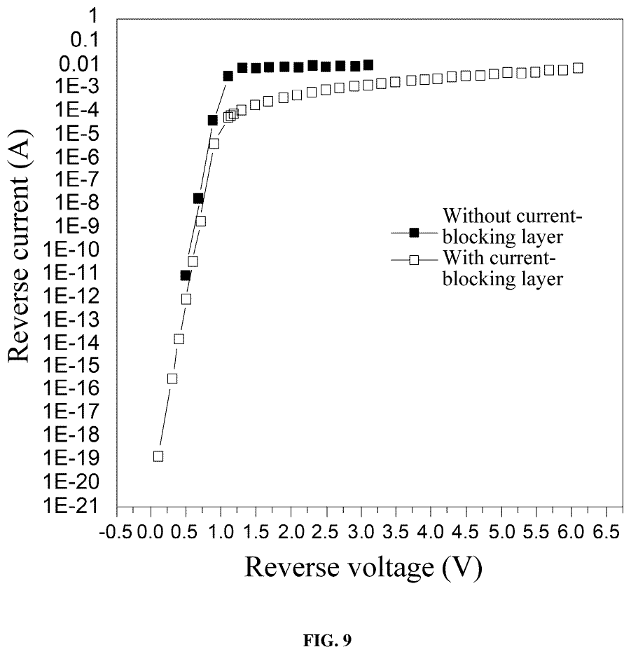

FIG. 8 and FIG. 9 show the comparison of the magnitude of the reverse current and the forward current with the introduction of the current-blocking layer 4 and without the introduction of the current-blocking layer 4 when the programmable medium layer 5 is in a low-resistance state. Simulation results show that the introduction of the current-blocking layer 4 has a more significant effect on reducing the reverse current in FIG. 8 than on reducing the forward current in FIG. 9.

Furthermore, the current-blocking layer 4 made of the insulating material will also reduce the forward current to a certain extent. Specifically, the introduction of the current-blocking layer 4 aims to reduce the reverse current of the memory cell in the idle state, thereby ensuring the stable operation of memory units in 3D stacking. However, while the reverse current is reduced, the forward current is also reduced to some extent, and therefore, other working states may be affected, as shown in FIG. 8. It should be additionally noted that: 1. Programming of the storage medium, that is, the working state (1), is driven by the electric field, and the programmable medium is still in an insulating state, which does not have a high requirement for the magnitude of the forward current. Therefore, the introduction of the current-blocking layer 4 will not affect the “write” working state as long as it does not affect the breakdown electric field in the insulating storage medium layer, as shown in FIG. 7. 2. Data reading, that is, working state (2), has a specific requirement for the magnitude of the forward current; however, the purpose of reading data can be achieved by appropriately increasing the reading voltage and/or reducing the threshold current. Therefore, the introduction of the insulating current-blocking layer 4 will not affect the “read” working state. In other words, the present disclosure improves the performance of working state (3) while not affecting the working states (1) and (2).

The present disclosure has the following beneficial effects:
1. The difference from the prior art lies in the fact that the prior art uses a semiconductor material as an intermediate layer (or buffer layer) to regulate the reverse leakage current. Typically, to reduce the leakage current, it is necessary to increase the thickness of the intermediate layer. Therefore, there is a contradiction between reducing the leakage current and reducing the footprint, and a trade-off needs to be made. In contrast, on the basis of the original programmable medium layer, the present disclosure adds a current-blocking layer made of a corresponding insulating layer material. Optimization can be achieved by adjusting the physical parameters such as the bandgap width and dielectric constant of the current-blocking layer, rather than the thickness of the insulating layer. Therefore, there is no contradiction between reducing the leakage current and reducing the area occupied.
2. The typical application of the present disclosure can ensure an extremely low reverse PN junction current. An extremely low reverse current can still be ensured even with a small layer thickness and a small chip area occupation.
3. The process cost can be further reduced by applying amorphous thin films. Therefore, the present disclosure can achieve low-cost, high-density storage.

Each embodiment in the description is described in a progressive mode, each embodiment focuses on differences from other embodiments, and references can be made to each other for the same and similar parts between embodiments.

Particular examples are used herein for illustration of principles and implementation modes of the present disclosure. The descriptions of the above embodiments are merely used for assisting in understanding the method of the present disclosure and its core ideas. In addition, those of ordinary skill in the art can make various modifications in terms of particular implementation modes and the scope of application in accordance with the ideas of the present disclosure. In conclusion, the content of the description shall not be construed as limitations to the present disclosure.

What is claimed is:

1. A programmable heterojunction memory device with current blocking, wherein the memory device comprises: a first electrode, a current-blocking heterojunction insulating medium layer, and a second electrode that are sequentially connected;
the current-blocking heterojunction insulating medium layer comprises: a current-blocking layer and a programmable medium layer; and
the current-blocking layer and the programmable medium layer use different insulating media;
the first electrode and the second electrode are made of designated matching materials; a bandgap width of the current-blocking layer is smaller than a bandgap width of the programmable medium layer; and no additional contact potential barrier is formed between the current-blocking layer and the first electrode or the second electrode in direct contact.

2. The programmable heterojunction memory device with current blocking according to claim 1, wherein the insulating medium used for the programmable medium layer is an anti-fuse insulating medium, a resistive non-volatile storage medium, or a phase-change non-volatile storage medium.

3. The programmable heterojunction memory device with current blocking according to claim 2, wherein the anti-fuse insulating medium is made of silicon oxide or aluminum oxide.

4. The programmable heterojunction memory device with current blocking according to claim 1, wherein the insulating medium used for the current-blocking layer comprises a charge-transfer insulator or an electrical insulator.

5. The programmable heterojunction memory device with current blocking according to claim 4, wherein the charge-transfer insulator comprises a TiO₂, ZnO, or HfO₂ thin film.

6. The programmable heterojunction memory device with current blocking according to claim 4, wherein the electrical insulator comprises intrinsic SiC.

7. The programmable heterojunction memory device with current blocking according to claim 1, wherein the current-blocking layer is in a crystalline, polycrystalline, or amorphous form; and the current-blocking layer is an amorphous HfO₂ thin film, amorphous SiC thin film, or amorphous silicon thin film.

8. The programmable heterojunction memory device with current blocking according to claim 1, wherein the designated matching materials comprise four sets of matching materials:
the first electrode is a P-type semiconductor or conductor, and the second electrode is an N-type semiconductor; or
the first electrode is a P-type Schottky metal, and the second electrode is an N+ semiconductor or conductor; or
the first electrode is an N+ semiconductor or conductor, and the second electrode is a P+ semiconductor; or
the first electrode is an N-type Schottky metal, and the second electrode is a P+ semiconductor or conductor.

9. The programmable heterojunction memory device with current blocking according to claim 8, wherein the P-type Schottky metal is Au or Pt.

10. The programmable heterojunction memory device with current blocking according to claim 8, wherein the N-type Schottky metal is Al.
